(19) United States
(12) Patent Application Publication
(10) Pub. No.: US 2006/0145240 A1
(43) Pub. Date: Jul. 6, 2006

(54) Memory devices and methods of operating the same

(76) Inventors: Yoon-Dong Park, Yongin-si (KR); Won-Joo Kim, Suwon-si (KR); Sang-Hun Jeon, Seoul (KR)

Correspondence Address: HARNESS, DICKEY & PIERCE, P.L.C., P.O. BOX 8910, RESTON, VA, 20195, US

(21) Appl. No.: 11/325,599

(22) Filed: Jan. 5, 2006

(30) Foreign Application Priority Data
Jan. 6, 2005 (KR) 10-2005-0001141

(51) Int. Cl. H01L 29/788

(52) U.S. Cl. 257/315

(57) ABSTRACT

A memory device may include a first memory unit and a second memory unit. The first memory unit may include a first storage node storing data using a first method. The second memory unit may include a second storage node using a second method. The second method may be different than the first method, and the first memory unit and the second memory unit may share a source and a drain.

### PRIORITY STATEMENT

This application claims priority under 35 U.S.C. § 119 to Korean Patent Application No. 10-2005-0001141, filed on Jan. 6, 2005, in the Korean Intellectual Property Office (KIPO), the entire contents of which are incorporated herein by reference.

### BACKGROUND

1. Field of the Invention

Example embodiments of the present invention relate to semiconductor memory devices, for example, multi-bit non-volatile memories (NVM) and methods of operating the same.

2. Description of the Related Art

A related art semiconductor memory device may be classified as a volatile memory device or non-volatile memory device. A volatile memory device such as a dynamic random access memory (DRAM) device may be used for storing and/or processing data while electric power is supplied to an apparatus. The apparatus may be, for example, a computer, mobile phone, a digital camera, or the like.

On the other hand, non-volatile memory devices may retain their data when power is turned off. A non-volatile memory device may use a threshold voltage transition of a transistor, charge displacement or variation of resistance. Non-volatile memory devices using the threshold voltage transition of a transistor may include, for example, flash memory devices using a floating gate as a storage node, SONOS memory devices using a charge trap as a storage node, or the like. A non-volatile memory device using charge displacement may be, for example, a ferroelectric memory (FRAM) including a nano-crystal or a polymer. Non-volatile memory devices using resistance variation may include a magnetic random access memory (MRAM), phase-change random access memory (PRAM), resistance random access memory (RRAM) or a polymer memory. In non-volatile memory devices, memory capacity may be limited by the processing power.

### SUMMARY OF THE INVENTION

Example embodiments of the present invention provide hybrid, multi-bit, non-volatile memory devices and methods of operating the same.

A memory device according to an example embodiment of the present invention may include a first memory unit and a second memory unit. The first memory unit may include a first storage node for storing data based on a first method. The second memory unit may include a second storage node for storing data based on a second method. The second method may be different from the first and the first and second memory units may share a source and a drain.

In example embodiments of the present invention, the first memory unit may store data using a variation of a threshold voltage of a channel depending on whether the first storage node stores charge or not, and the second memory unit may stores data using a variation of the resistance of the second storage node. The second storage node may be formed of a dielectric layer, a ferroelectric layer, a ferro-magnetic layer, a phase changing layer, a transition metal oxide, or a polymer.

Example embodiments of the present invention may further include at least one channel, at least one source and at least one drain. The at least one source and at least one drain may be connected to opposite ends of the at least one channel. The first storage node may store a charge, and the second storage node may have a variable resistance and be connected between the at least one source and the at least one drain.

In example embodiments of the present invention, the channel may be formed on a semiconductor substrate. The source may be a conductive source formed at one end of the channel and the drain may be a conductive drain formed at an opposite end of the channel. A first insulating layer may be formed on the channel and at least a portion of the source and the drain. The first storage node may be formed on the first insulating layer, and/or a second insulating layer may be formed on the storage node. A control gate may be formed on the second insulating layer, and/or a third insulating layer may be formed on the control gate. The second storage node may be formed on the third insulating layer, and a switch may couple the second storage node to the source and the drain. A fourth insulating layer may insulate the first storage node from the control gate.

In example embodiments of the present invention, the second storage node may be comprised of a material with variable resistance in response to an applied voltage, for example, at least one of Nb₂O₅, Cr doped SrTiO₃, ZrOₓ, GST (GeSbₓTe_{y}), NiO, TiO₂ and HfO. The switch may be formed of a transition metal oxide, which may be electrically conductive in response to a voltage greater than a threshold voltage, for example, V₂O₅ or TIO. The first storage node may be formed of poly silicon, silicon nitride, silicon dot or metal dot. One or more of the first insulating layer, the second insulating layer and the third insulating layer may include a silicon oxide layer.

In example embodiments of the present invention, the semiconductor substrate may be a p-type or an n-type semiconductor substrate and the conductive source and drain may be a p-type or n-type source and a p-type or n-type drain.

A cell array according to an example embodiment of the present invention may include a plurality of unit cells. Each unit cell may include a memory device according to one or more example embodiments of the present invention. The second storage nodes of the unit cells may be connected to each other, and the source of each unit cell may be connected to the drain of a neighbouring unit cell. A switch may couple the second storage node to the source and the drain, and the switch in each memory device may be connected to a switch of a neighbouring cell.

In a method of operating the cell array according to an example embodiment of the present invention, a cell of operation may be selected from among the cell array. Channels in each unselected cell may be turned on by applying a pass voltage to the control gates of the unselected cells. An operating voltage may be applied to the control gate of the selected cell such that the first storage node of the selected cell may be used as a first storage medium. A second operating voltage may be applied to the source and the drain of the selected cell such that the second storage node of the selected cell may be used as a second storage medium.

In example embodiments of the present invention, an erasing operation may include applying erasing voltage to the second storage nodes of both ends of the cell array.

In a method of operating a memory device, according to an example embodiment of the present invention, a voltage may be applied between the channel and a control gate formed between the first storage node and the second storage node to turn on the channel such that the first storage node becomes a first storage medium. A voltage may be applied between the source and the drain to turn on a switch coupling the second storage node to the source and the drain such that the second storage node becomes a second storage medium.

In a writing operation, according to an example embodiment of the present invention, a voltage lower than a threshold voltage may be applied between the source and the drain to turn off the switch. A writing voltage may be applied between the channel and the control gate, and charge may be accumulated in the first storage node. Another writing operation may include applying 0V between the channel and the control gate to turn off the channel, and lowering the resistance of the second storage node by applying a writing voltage between the source and the drain to turn on the switch.

In a reading operation according to an example embodiment of the present invention, a voltage lower than a threshold voltage may be applied between the source and the drain to turn off the switch, and a variation of threshold voltage of the channel may be read by applying a reading voltage between the channel and the control gate. Another reading operation may include applying 0V between the channel and the control gate to turn off the channel, and measuring a variation of current passing through the second storage node by applying a reading voltage between the source and the drain to turn on the switch.

In an erasing operation, according to an example embodiment of the present invention, a voltage lower than a threshold voltage may be applied between the source and the drain to turn off the switch, and an erasing voltage may be applied between the channel and the control gate to erase a charge stored in the first storage node. Another erasing operation may include applying 0V between the channel and the control gate to turn off the channel, and increasing the resistance of the second storage node by applying an erasing voltage between the source and the drain to turn on the switch.

In example embodiments of the present invention, the channel may be formed vertically on a first insulating layer, and the first storage node may cover side surfaces and an upper surface of the channel. The source and the drain may be coupled to the second storage node via a switch.

In example embodiments of the present invention, a first channel may be doped with a first conductive impurity and a second channel may be doped with a second conductive impurity. The first and second channels may be stacked vertically on a first insulating layer and may be separated by a second insulating layer. A third insulating layer may cover the first storage node, and a first source and a first drain may be connected to respective ends of the first channel. A second source and a second drain may be connected to respective ends of the second channel. The first storage node may be formed on side surfaces and an upper surface of the first and second channels, the control gate may be formed on the third insulating layer, and/or the second storage node may be connected between an upper most source and an upper most drain in the vertical stack.

### BRIEF DESCRIPTION OF THE DRAWINGS

The present invention will become more apparent by describing in detail example embodiments illustrated in the attached drawings in which:

FIG. 1 is a cross sectional view of a memory device according to an example embodiment of the present invention;

FIGS. 2 and 3 are cross sectional views of a memory device according to an example embodiment of the present invention;

FIG. 4 is a cross sectional view of a cell array according to another example embodiment of the present invention;

FIG. 5 is a perspective view of a memory device according to another example embodiment of the present invention;

FIG. 6 is a perspective view of a memory device according to another example embodiment of the present invention; and

FIG. 7 is a circuit diagram of a cell of a memory device according to an example embodiment of the present invention.

### DETAILED DESCRIPTION OF EXAMPLE EMBODIMENTS OF THE PRESENT INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

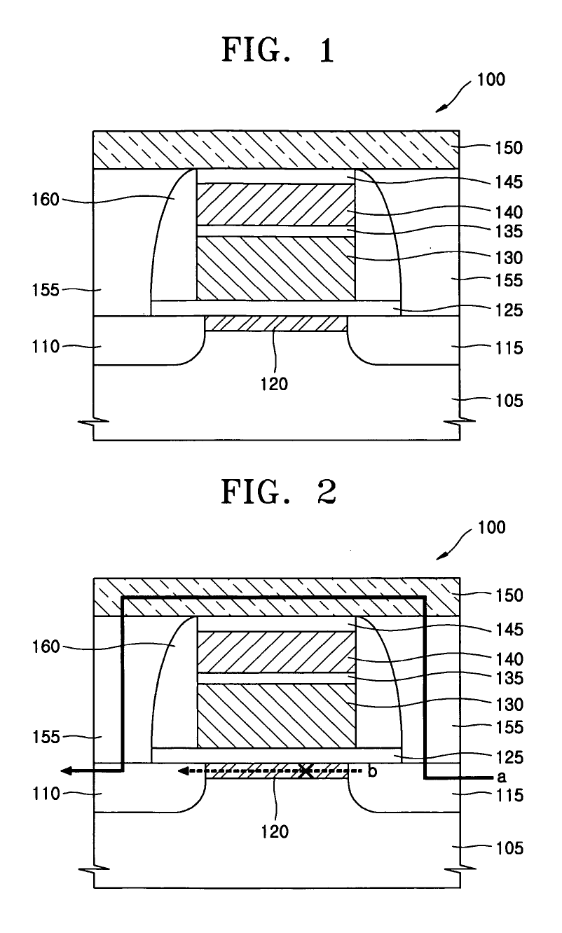

FIG. 1 is a cross sectional view of a memory device (e.g., a hybrid non-volatile memory device) according to an example embodiment of the present invention.

Referring to FIG. 1, a hybrid non-volatile memory device 100 may be a storage medium including a plurality of circuits (e.g., two parallel circuits) selectively using a plurality of storage nodes. For example, as shown in FIG. 1, the memory device 100 may include a storage node 130 and a resistance node 150. The storage node 130 may be, for example, a threshold voltage transition memory device such as a flash memory device, a SONOS memory device or the like. The storage node 130 may float between a channel 120 of a semiconductor substrate 105 and a control gate 140.

In one example, a first insulating layer 125 may be formed between the channel 120 and the storage node 130. A second insulating layer 135 may be formed between the storage node 130 and the control gate 140. The storage node 130 may be formed of a poly-silicon, a silicon-nitride layer, a silicon dot, a metal dot or any other metallic or semi-metallic material. A silicon-oxide layer, through which a charge tunnel may be formed, may be used as the first insulating layer 125 and/or the second insulating layer 135. Although, the first insulating layer 125 and/or the second insulating layer 135 are discussed herein as being formed of a silicon-oxide material, any other material or oxide material having similar, or substantially similar, properties may be used. The control gate 140 may be formed of a compound layer including poly-silicon (e.g., metal on poly-silicon, metal silicide on a poly-silicon or any other metallic and semi-metallic combination or compound).

A source 110 and a drain 115 may be formed on respective ends of the channel 120. In one example, if the semiconductor substrate 105 is a p-type substrate, the source 110 and/or the drain 115 may be doped as an n-type substrate. The source 110 and/or the drain 115 may be formed by doping the substrate 105 using n-type impurities.

The drain 115, the channel 120 and/or the source 110 may form a circuit. The control gate 140 may control the channel 120 to be turned-on or turned-off. For example, if a voltage higher than a threshold voltage is applied to the control gate 140, the channel 120 may be turned-on. In another example, if a voltage lower than the threshold voltage is applied to the control gate 140, the channel 120 may be turned-off. In example embodiments of the present invention, the source 110, the drain 115, the channel 120, the control gate 140 and/or the storage node 130 may form a memory device. The memory device may store a plurality of bits, for example, greater than 2 bits.

The resistance node 150 may be formed to cover at least a portion of a third insulating layer 145, which may be formed on the control gate 140. The third insulating layer 145 may comprise, for example, silicon oxide or any other suitable oxide material. The resistance node 150 may be connected to the source 110 and the drain 115 through a switch 155.

The switch 155 may be formed of a transition metal oxide (TMO), which may become electrically conductive in response to a voltage greater than the threshold voltage applied to the switch 155. The TMO may be, for example, V₂O₅, TiO or any other suitable transition metal oxide. The switch 155 may be insulated from the storage node 130 and/or the control gate 140 by a fourth insulating layer 160.

In one example, the switch 155 may be formed of VOₓ, which may have a lower conductance. In this example, if a voltage lower than a threshold voltage (e.g., 1.5V) is applied to the switch 155, at least a portion (e.g., most) of the applied voltage may be dropped at both ends of the switch 155. If a voltage greater than the threshold voltage is applied to the switch 155, the switch 155 may become conductive and the electric current passing through the switch 155 may increase. In this example, the switch 155 may act as a diode.

The resistance of the resistance node 150 may vary according to the applied voltage. The resistance node 150 may be formed of, for example, Nb₂O₅, Cr doped SrTiO₃, ZrOₓ, GST (GeSbₓTe_{y}), NiO, TiO₂, HfO or any other suitable material with variable resistance.

When a voltage higher than a writing voltage is applied to the resistance node 150, composed of, for example NiO, the resistance of the resistance node 150 may decrease. In this example, if a reset voltage is applied to the resistance node 150, the resistance may increase. If the resistance is decreased (e.g., once) by applying the writing voltage, the lower resistance may be maintained until the reset voltage is applied. In at least one example embodiment, the variation of resistance may be maintained after removal of the voltage. The resistance node 150 may be used as a storage medium of the non-volatile memory device.

Since the applied voltage is distributed between the switch 155 and the resistance node 150 according to the resistance, an electric current passing through the switch 155 and the resistance node 150 may form a wave based on the resistance of the resistance node 150. The writing voltage and erasing voltage may be selected based on the wave.

Still referring to FIG. 1, the drain 115, the switch 155, the resistance node 150 and/or the source 110 may form another circuit. Flow of electric current to the resistance node 150 may be controlled by turning the switch 155 on or off. In this example, the drain 115, the switch 155, the source 110, and/or the resistance node 150 may form another memory device, which may store a plurality of bits (e.g., more than 2 bits).

Similar to the above example, two circuits (e.g., parallel circuits) may connect the drain 115 to the source 110. One of the two parallel circuits may be selected by switching the channel 120 on or off. In this example, the hybrid multi-bit non-volatile memory device 100 may store a plurality of bits with a circuit using the storage node 130 and/or a plurality of bits with a circuit using the resistance node 150.

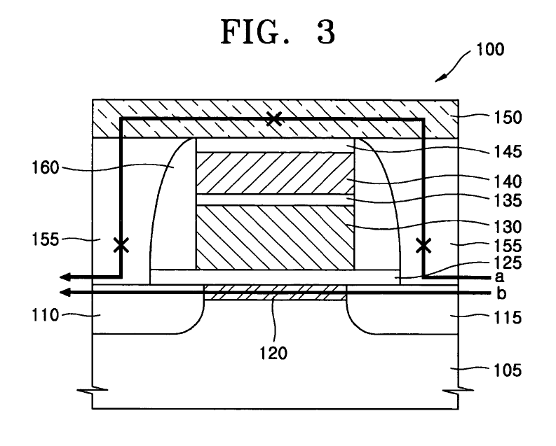

FIGS. 2 and 3 are cross sectional views of a memory device according to an example embodiment of the present invention. As shown, the channel 120 may be turned off by applying, for example, about 0V between the control gate 140 and the channel 120. By applying a voltage greater than the threshold voltage of the switch 155 between the source 110 and the drain 115, an electric current may flow from the drain 115 to the source 110 through the resistance node 150 along current path a. Since the channel 120 is off, the electric current may not flow from the drain 115 to the source 110 through the channel 120 along current path b. In this example, resistance node 150 may be used as a storage medium.

A writing operation of the resistance node 150 may be performed by applying a writing voltage between the source 110 and the drain 115. In this example embodiment, the switch 155 may be turned on and the writing voltage may be applied to the resistance node 150 to reduce resistance of the resistance node 150.

In a reading operation of the resistance node 150, a reading voltage may be applied between the source 110 and the drain 150. The reading voltage may be greater than the threshold voltage of the switch 155, the switch 155 may be turned on. The electric current passing through the resistance node 150 may be measured. If the measured resistance is low (e.g., lower than a given level), the resistance node 150 may be in a write state, whereas if the resistance measured is high (e.g., higher than a given level), the resistance node may be in an erase state.

An erasing operation may be performed by applying an erasing voltage between the source 110 and the drain 115. The erasing voltage may be higher than the threshold voltage of the switch 155 and may be lower than the writing voltage. In this example, the switch 155 may be on and the resistance of the resistance node 150 may increase.

Referring to FIG. 3, the channel 120 may be switched on in response to a voltage higher than the threshold voltage of the channel 120 applied between the control gate 140 and the channel 120. The switch 155 may be deactivated in response to a voltage lower than the threshold voltage of the switch 155 appliedbetweenthe source 110 and the drain 115. In this case, electric current may not flow through the resistance node 150, and the storage node 130 may be used as a storage medium.

A writing operation of the storage node 130 may be performed by applying a different writing voltage between the channel 120 and the control gate 140. In this example, a charge may be stored in the storage node 130 by tunnelling from the channel 120 through the first insulating layer 125 and/or injecting a hot carrier. When the charge is accumulated in the storage node 130, the threshold voltage of the channel 120 composed of, for example, a p-type material may be increased.

A reading operation of the storage node 130 may be performed by reading variations in the threshold voltage of the channel 120. A reading voltage, which may be between the writing voltage and the increased threshold voltage, may be applied to the channel 120 and/or the control gate 140. If the charge is stored in the storage node 130, the channel 120 may be off, whereas if the charge is not stored in the storage node 130, the channel 120 may be on.

In an erasing operation of the storage node 130, an erasing voltage may be applied between the channel 120 and the control gate 140. In one example, the charge of the storage node 130 may be erased by applying a negative voltage to the control gate 140.

The memory device 100 may perform a multi-bit operation using a hybrid combination of memory devices or units using different methods of storing data. For example, one memory unit may use a variation of threshold voltage, where the threshold voltage may be varied according to charge stored in the storage node 130. Another memory unit may use a variation of the resistance of the resistance node 150.

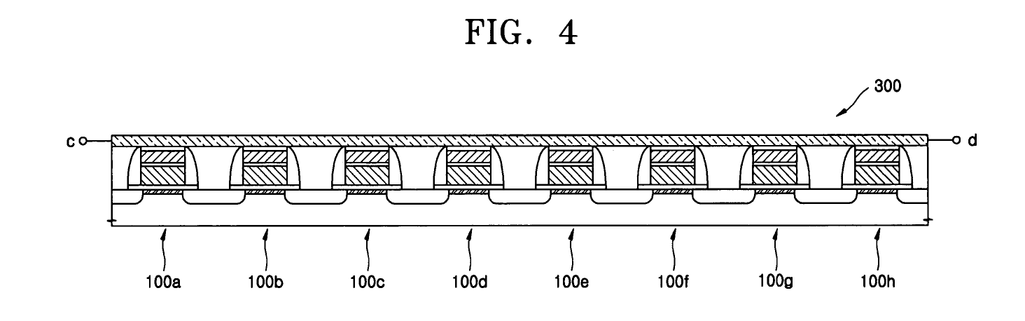

FIG. 4 is a cross sectional view of a cell array (e.g., a NAND cell array) 300 according to another example embodiment of the present invention.

Referring to FIG. 4, the NAND cell array 300 may include a plurality of unit cells 100a, 100b, 100c, 100d, 100e, 100f, 100g and/or 100h arranged and/or connected on a semiconductor substrate in, for example, a uni-axial or any other suitable formation. Each of the unit cells 100a, 100b, 100c, 100d, 100e, 100f, 100g and/or 100h may have a structure identical, or substantially identical, to the memory device 100 shown in FIG. 1. Therefore, a detailed explanation of each of the unit cells 100a, 100b, 100c, 100d, 100e, 100f, 100g and 100h is omitted for the sake of brevity.

As shown in FIG. 4, eight unit cells may be formed on the semiconductor substrate. However, the number of the unit cells may differ according to the structure of the NAND cell array 300.

Resistance nodes of the unit cells 100a, 100b, 100c, 100d, 100e, 100f, 100g and 100h may be connected to each other. Also, the source of each unit cell (e.g., 100c) may be connected to the drain of the neighboring unit cell (e.g., 100b). If channels of all, or substantially all, the unit cells 100a, 100b, 100c, 100d, 100e, 100f, 100g and/or 100h are on, a conductive path from the drain of the right unit cell 100h to the source of the left unit cell 100a may be formed.

When a writing operation or a reading operation is performed on a storage node of a unit cell such as unit cell 100e, a pass voltage greater than the threshold voltage may be applied to turn on the channels of the other unit cells 100a, 100b, 100c, 100d, 100f, 100g and/or 100h. After turning on the channels of the other unit cells 100a-100d and 100f-100h, the writing voltage or the reading voltage may be applied to the control gate of the unit cell 100e. The writing operation or the reading operation may be performed on the storage node of the unit cell 100e.

When a writing operation or a reading operation is performed on a resistance node of a unit cell such as the unit cell 100e, a pass voltage greater than the threshold voltage may be applied to the control gates to turn on the channels of the other unit cells 100a, 100b, 100c, 100d, 100f, 100g and/or 100h. In addition, 0V may be applied to the control gate of the unit cell 100e to turn off the channel of the unit cell 100e. For example, a voltage sufficient to turn on a switch between the source and the drain of the unit cell 100e and to operate the resistance node of the unit cell 100e may be applied, and the writing or reading operation may be performed on the resistance node of the unit cell 100e.

An erasing operation of the cell array 300 may be similar, or substantially similar, to an erasing operation of a conventional or related art memory device (e.g., flash memory device). For example, the erasing operations on resistance nodes of the cell array 300 may be performed, for example, concurrently or simultaneously by applying an erasing voltage between ends c and d of the cell array 300. The applied erasing voltage may be determined by calculating the voltage drop across all, or substantially all, of the unit cells.

Memory capacity may be expanded using the cell array 300 including a plurality of memory devices according to example embodiments of the present invention.

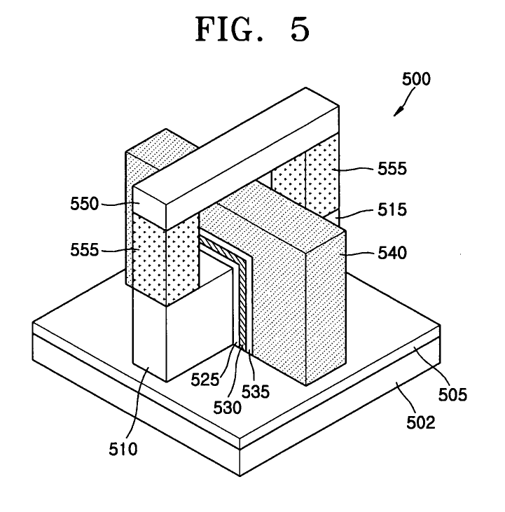

FIG. 5 is a perspective view of a memory device, according to another example embodiment of the present invention. As shown, a hybrid non-volatile memory device 500 may have an Fin-FET structure. A channel (not shown) may be formed (e.g., vertically formed) on a first insulating layer 505. The first insulating layer 505 may be formed on a semiconductor substrate 502. The channel may be formed inside a control gate 540 that may cover side surfaces and/or an upper surface of the channel.

A first storage node 530 for storing a charge may be formed between the channel and the control gate. The first storage node 530 may be insulated from the channel by a second insulating layer 525 and may be insulated from the control gate 540 by a third insulation layer 535. The channel may be connected to a source 510 and a drain 515. The source 510 and the drain 515 may be connected to a second storage node 550 through a switch 555. The second storage node 555 may have a variable resistance.

The first storage node 530 may be formed of poly silicon, silicon nitride, a silicon dot, a metal dot or any other suitable metallic or semi-metallic material. The resistance of the second storage node 550 may be varied in response to an applied voltage. The second storage node 550 may be formed of, for example, Nb₂O₅, Cr doped SrTiO₃, ZrO_{X}, GST (GeSbₓTe_{y}), NiO, TiO₂, HfO or any other suitable oxide material.

The Fin-FET structure of the memory device 500 may be similar, or substantially similar, to the memory device 100 shown in FIG. 1 except for the Fin-FET structure. A method of operating the Fin-FET structure of the memory device 500 may be understood to those skilled in the art. Therefore, a detailed explanation of the method of operation of the memory device 500 is omitted for the sake of brevity.

FIG. 6 is a perspective view of a cell, for example, a memory device (e.g., a CMOS Fin-FET cell) according to another example embodiment of the present invention. As shown, a CMOS Fin-FET cell 600 may be similar, or substantially similar, to the Fin-FET cell of the memory device 500 except for a CMOS structure. A channel (not shown) may be divided into a first channel doped with, for example, an n-type impurity, and a second channel doped with, for example, a p-type impurity to form the CMOS structure. The second source 610b and the second drain (not shown) connected to the first channel may be doped with the p-type impurity, and the first source 610a and the first drain 615a connected to the second channel may be doped with the n-type impurity. The first source 610a and second source 610b may be separated by an insulating layer 612, and The first drain 615a and the second drain (not shown) may be separated by an insulating layer (not shown).

The first and second channels may be formed on a first insulating layer 605 on a semi-conductor layer 602 and a first storage node 630 may be used to store a charge between the channels and a control gate 640. The storage node 630 may be insulated from the channels by a second insulating layer 625 and may be insulated from the control gate 640 by a third insulating layer 635. The first source 610a and the first drain 615a connected to the second channel may be connected to a second storage node 650 with a variable resistance through a switch 655. The second source 610b and the second drain connected to the first channel may be connected to another switch 655 by a metal contact (not shown). In one example, a switch 655 may connect the sources 610a and 610b in parallel, and the first drain 615a and the second drain in parallel.

The CMOS Fin-FET cell 600 may be similar, or substantially similar, to the memory device 100 shown in FIG. 1 except for the Fin-FET structure. Accordingly, a method of operating the CMOS Fin-FET cell 600 will be understood to those skilled in the art, and a detailed explanation of the method of the operation of the CMOS Fin-FET cell 600 is omitted for the sake of brevity.

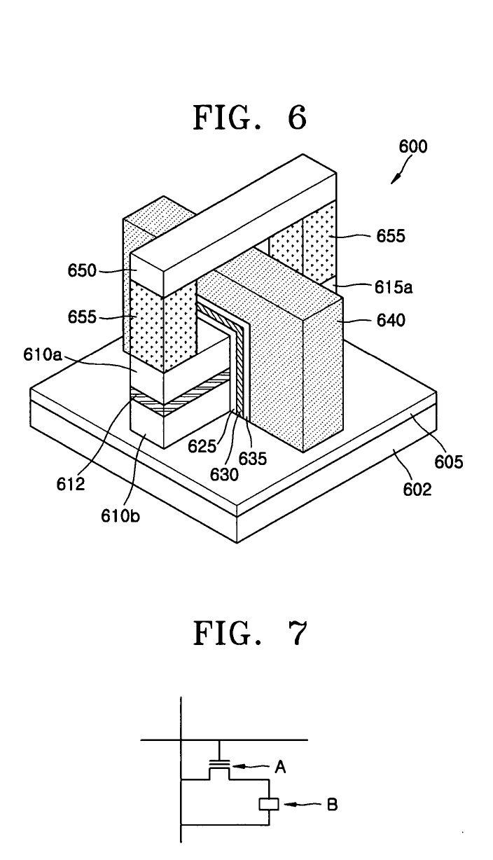

FIG. 7 is a circuit diagram of a cell of a memory device according to another example embodiment of the present invention. Referring to FIG. 7, the hybrid non-volatile memory device is not limited to a combination of two elements, for example, a flash memory and/or a resistance memory.

A unit cell of the memory device may include a first memory unit A and a second memory unit B. The first memory unit A may include a first storage node for storing a charge. The first memory unit A may store data using a variation of a threshold voltage which may be varied based on the storage of charge at the first storage node. The first storage node may be formed of poly silicon, silicon nitride or any other suitable material. For example, the first memory unit A may be operated similarly to a flash memory device, a SONOS memory device or the like.

The second memory unit B may include a second storage node for storing data that may use a different method than the first storage node. The second memory unit B may store data using, for example, a resistance variation of the second storage node. For example, the second storage node may be formed of a dielectric layer, a ferroelectric layer, a ferro-magnetic layer, a phase changing layer, a transition metal oxide, a polymer or the like.

A method of operating the cell array will be understood by those skilled in the art by referring to the method of operating the cell array structure of the memory device 300 as illustrated in FIG. 4.

While the present invention has been particularly shown and described with reference to example embodiments illustrated in the drawings, it will be understood by those of ordinary skill in the art that various changes in form and details may be made therein without departing from the spirit and scope of the present invention as defined by the following claims.

What is claimed is:

1. A memory device, comprising:
a first memory unit including a first storage node storing data using a first method; and
a second memory unit including a second storage node using a second method; wherein
the first method and the second method are different, and
the first memory unit and the second memory unit share a source and a drain.

2. The memory device of claim 1, wherein
the first memory unit stores data using a variation of a threshold voltage of a channel depending on whether the first storage node stores charge or not, and
the second memory unit stores data using a variation of the resistance of the second storage node.

3. The memory device of claim 1, wherein the first storage node is formed of poly silicon, silicon nitride, silicon dot or metal dot.

4. The memory device of claim 1, wherein the second storage node is formed of a dielectric layer, a ferroelectric layer, a ferro-magnetic layer, a phase changing layer, a transition metal oxide or a polymer.

5. The memory device of claim 1, further including,
at least one channel,
at least one source and at least one drain connected to opposite ends of the at least one channel, wherein
the first storage node stores a charge, and
the second storage node has a variable resistance and is connected between the at least one source and the at least one drain.

6. The memory device of claim 5, wherein
the channel is formed on a semiconductor substrate,
the source is a conductive source formed at one end of the channel and the drain is a conductive drain formed at an opposite end of the channel,
a first insulating layer is formed on the channel and at least a portion of the source and the drain,
the first storage node is formed on the first insulating layer,
a second insulating layer is formed on the storage node,
a control gate is formed on the second insulating layer,
a third insulating layer is formed on the control gate,
the second storage node is formed on the third insulating layer, and
a switch couples the second storage node to the source and the drain.

7. The memory device of claim 6, wherein the second storage node is comprised of a material with variable resistance in response to an applied voltage.

8. The memory device of claim 6, wherein the second storage node is formed of at least one of Nb₂O₅, Cr doped SrTiO₃, ZrOₓ, GST (GeSbₓTe_{y}), NiO, TiO₂ and HfO.

9. The memory device of claim 6, wherein the switch is formed of a transition metal oxide, which is electrically conductive in response to a voltage greater than a threshold voltage.

10. The memory device of claim 6, wherein the switch is formed of a transition metal oxide, such as, V₂O₅ or TIO.

11. The memory device of claim 6, wherein the first storage node is formed of poly silicon, silicon nitride, silicon dot or metal dot.

12. The memory device of claim 6, wherein each of the first insulating layer, the second insulating layer and the third insulating layer include a silicon oxide layer.

13. The memory device of claim 6, wherein the semiconductor substrate is a p-type semiconductor substrate and the conductive source and drain are an n-type source and an n-type drain, respectively.

14. The memory device of claim 6, further including,
a fourth insulating layer insulating the first storage node from the control gate.

15. A cell array comprising a plurality of the memory devices claimed in claim 1.

16. A cell array comprising a plurality of unit cells, each unit cell including a memory device as claimed in claim 5, wherein the second storage nodes of the unit cells are connected to each other, and the source of each unit cell is connected to the drain of a neighbouring unit cell.

17. The cell array of claim 16, wherein each memory device further includes, a switch coupling the second storage node to the source and the drain, and wherein
the switch in each memory device is connected to a switch of a neighbouring cell, respectively.

18. The cell array of claim 16, wherein each second storage node is comprised of a material with variable resistance in response to an applied voltage.

19. The cell array of claim 16, wherein each second storage node is formed of a material including at least one of Nb₂O₅, Cr doped SrTiO₃, ZrOₓ, GST (GeSbₓTe_{y}), NiO, TiO₂ and HfO.

20. The cell array of 16, wherein the switch in at least one memory device is formed of a transition metal oxide which is electrically conductive in response to a voltage greater than a threshold voltage.

21. The cell array of claim 16, wherein the switch in at least one memory device is formed of V₂O₅ or TIO.

22. The cell array of claim 16, wherein the first storage node is formed of poly silicon, silicon nitride, silicon dot or metal dot.

23. A method of operating the cell array of claim 16, the method comprising:
selecting a cell of operation among the cell array;
turning on channels in each unselected cell by applying a pass voltage to the control gates of the unselected cells;
using the first storage node of the selected cell as a first storage medium by applying an operating voltage to the control gate of the selected cell; and
using the second storage node of the selected cell as a second storage medium by applying a second operating voltage to the source and the drain of the selected cell.

24. The method of claim 23, wherein an erasing operation on second storage nodes of memory devices in the cell array includes,
applying erasing voltage to the second storage nodes of both ends of the cell array.

25. A method of operating the memory device of claim 5, comprising:
applying a voltage between the channel and a control gate formed between the first storage node and the second storage node to turn on the channel such that the first storage node becomes a first storage medium; and
applying a voltage between the source and the drain to turn on a switch coupling the second storage node to the source and the drain such that the second storage node becomes a second storage medium.

26. The method of claim 25, wherein a writing operation on the first storage medium includes,
applying a voltage lower than a threshold voltage between the source and the drain to turn off the switch,
applying a writing voltage between the channel and the control gate, and
accumulating a charge in the first storage node.

27. The method of claim 25, wherein a writing operation on the second storage medium includes,
applying 0V between the channel and the control gate to turn off the channel, and
lowering the resistance of the second storage node by applying a writing voltage between the source and the drain to turn on the switch.

28. The method of claim 25, wherein a reading operation on the first storage medium includes,
applying a voltage lower than a threshold voltage between the source and the drain to turn off the switch, and
reading a variation of threshold voltage of the channel by applying a reading voltage between the channel and the control gate.

29. The method of claim 25, wherein a reading operation on the second storage medium includes,
applying 0V between the channel and the control gate to turn off the channel, and
measuring a variation of current passing through the second storage node by applying a reading voltage between the source and the drain to turn on the switch.

30. The method of claim 25, wherein an erasing operation on the first storage medium includes,
applying a voltage lower than a threshold voltage between the source and the drain to turn off the switch, and
applying an erasing voltage between the channel and the control gate to erase a charge stored in the first storage node.

31. The method of claim 25, wherein an erasing operation on the second storage medium includes,
applying 0V between the channel and the control gate to turn off the channel, and
increasing the resistance of the second storage node by applying an erasing voltage between the source and the drain to turn on the switch.

32. The memory device of claim 5, wherein
the channel is formed vertically on a first insulating layer, and
the first storage node covers side surfaces and an upper surface of the channel,

33. The memory device of claim 32, wherein the source and the drain are coupled to the second storage node via a switch, the switch being electrically conductive in response to a voltage greater than a threshold voltage.

34. The memory device of claim 32, wherein the first storage node is formed of poly silicon, silicon nitride, silicon dot or metal dot.

35. The memory device of claim 32, wherein the second storage node is composed of a material with variable resistance in response to an applied voltage.

36. The memory device of claim 32, wherein the second storage node is formed of at least one of Nb₂O₅, Cr doped SrTiO₃, ZrOₓ, GST (GeSbₓTe_{y}), NiO, TiO₂ and HfO.

37. The memory device of claim 5, further including,
a first channel doped with a first conductive impurity and a second channel doped with a second conductive impurity, the first and second channels being stacked vertically on a first insulating layer and separated by a second insulating layer,
a third insulating layer covering the first storage node; and
a first source and a first drain connected to respective ends of the first channel, and
a second source and a second drain connected to respective ends of the second channel, wherein
the first storage node is formed on side surfaces and an upper surface of the first and second channels,
the control gate is formed on the third insulating layer, and
the second storage node is connected between an upper most source and an upper most drain in the vertical stack.
